(19) United States
(12) Patent Application Publication
(10) Pub. No.: US 2008/0318154 A1
(43) Pub. Date: Dec. 25, 2008

(54) Ink-Less Printing

(75) Inventor: Christopher Anthony Wyres, Widnes (GB)

Correspondence Address: Levenfeld Pearlstein, LLC;Intellectual Property Department, 2 North LaSalle, Suite 1300, Chicago, IL, 60602, US

(73) Assignee: DATALASE LTD., Widnes (GB)

(21) Appl. No.: 12/089,028

(22) PCT Filed: Sep. 29, 2006
(86) PCT No.: PCT/GB2006/003641

§ 371 Date: Sep. 9, 2008

(30) Foreign Application Priority Data
Oct. 3, 2005 (GB) 0520115.7

(51) Int. Cl. G03F 7/025; G02B 26/00

(52) U.S. Cl. 430/270.1; 359/196

(57) ABSTRACT

A method of ink-less printing comprises the steps of: providing a source (1) for emitting an energy beam,—providing an array of programmable shutters (3), each adapted for selectively blocking or allowing passage of at least some of an energy beam therethrough; providing a substrate (4) including an additive susceptible to changing colour when energized by the energy beam emitted by the source; selectively allowing passage of at least some of the energy beam emitted by the source through the array of shutters; and, positioning the substrate in the path of the energy beam that has passed through the array of shutters such that at least one desired point on the substrate is energized by said beam thus causing the additive to change colour at said point.

### FIELD OF THE INVENTION

This invention relates to a method of ink-less printing and a system therefor.

### BACKGROUND TO THE INVENTION

In recent years, a concept of ink-less printing has been developed whereby additives are applied to, or in, substrates for marking. The additives are susceptible to colour change when energized by an energy beam. Such printing methods are distinct from charring or ablation marking wherein a substrate material itself is either evaporated or undergoes a compositional change to form a perceptible image on the substrate.

Traditionally, ink-less printing has necessitated the use of relatively large CO₂ lasers due to the high fluence levels required to initiate a colour change at each selected point on the substrate to be marked. Progressive scan or vector format imaging techniques have been the imaging forming methods of choice since only a single laser source is required, the laser or the substrate being steered relative to one another. The use of more than a single laser source has been generally prohibitively expensive.

The above-mentioned traditional ink-less printing methods and systems for implementing them have numerous disadvantages in that they require large printing apparatus with high energy consumption and can only image at relatively low resolution. There is therefore a need in the art for improved ink-less printing methods and systems therefor.

### SUMMARY OF THE INVENTION

In accordance with one aspect of the present invention, a method of ink-less printing comprises the steps of providing a source for emitting an energy beam, providing an array of programmable shutters, each adapted for selectively blocking or allowing passage of at least some of an energy beam therethrough, providing a substrate including an additive which is susceptible to changing colour when energized by the energy beam emitted by the source, selectively allowing passage of at least some of the energy beam emitted by the source through the array of shutters, and positioning the substrate in the path of the energy beam that has passed through the array of shutters such that at least one desired point on the substrate is energized by said beam thus causing the additive to change colour at said point.

In accordance with a second aspect of the present invention, an ink-less printing system comprises a source for emitting an energy beam, an array of programmable shutters, each adapted for selectively blocking or allowing passage of at least some of the energy beam therethrough, and a substrate including an additive susceptible to changing colour when energized by the energy beam emitted by the source, wherein, in use, the energy beam passing through the array of programmable shutters energizes at least one desired point on the substrate thus causing the additive to change colour at said point.

### DESCRIPTION OF THE INVENTION

The present applicants have developed compounds for applying to, or in, substrates for use in ink-less printing. Some of these compounds comprise additives susceptible to changing colour upon irradiation with light, which may be in the infrared, visible or ultraviolet region. Other additives are known in the art which are susceptible to changing colour when energized by, for example, other types of electromagnetic radiation, or an electron beam. The most practically important of these additives are colourless or transparent prior to being energized and change colour to one of a plurality of colours when energized depending on a fluence level of the incident energy, and the substrate. Appropriately coated substrates may be marked at high speed, at high resolution and in mono-tone, grey-scale, or full multi-tonal colour.

The present invention enables printing at very high resolution and in a short time owing to the programmable shutter array and matching of the energy source to the additive of the substrate. Printing of a relatively large, for example A4 paper size, image at high resolution in a time of a few seconds is envisaged. Such printing capability has heretofore not been achievable.

Various types of programmable optical shutter arrays are suitable for use in the present invention. Whilst optical shutter arrays are particularly suitable for use as the shutter arrays, other types of shutter may be used, depending on the type of energy beam emitted by the source.

A plurality of liquid crystals in a linear or matrix array may be utilized as an optical shutter array. The liquid crystals can be controlled to transmit light through selected regions of the liquid crystal array.

Liquid crystal devices may be of a reflective or back-lit type. In a reflective type liquid crystal device, incoming natural or artificial light is reflected but some of the reflected light is controlled to be blocked by the liquid crystal layers, thus creating a perceptible image. In a back-lit type liquid crystal device, a light source is disposed behind the liquid crystal layers which are controlled to allow passage or block light from the light source as desired to again create a perceptible image. Liquid crystal devices are therefore suitable for use as programmable optical shutters or photomasks. The resolution achievable with liquid crystal photomasks has improved in recent years with crystal cells being micron sized. Liquid crystal photomasks are currently most suitable for use in the present invention due to their relatively low cost.

However, other types of programmable optical shutters are becoming available such as microfluidic devices and solid state spatial light modulator devices.

In microfluidic devices, micron sized channels are formed in a substrate. The channels may be filled with two immiscible fluids having differing refraction indices. By controlling the location of the fluids, the path of a light beam can be bent such that the light is transmitted or refracted as it passes through the channel. Alternatively, two immiscible liquids, of which one does not transmit light at visible wavelengths, may be used to modulate transmission or reflection. Wavelengths other than in the visible region, for example near infrared, may be selected as the controllable wavelengths. Other microfluidic devices known to those skilled in the art may be equally applicable for use as the optical shutter array.

Solid state spatial light modulator devices typically comprise a diode-pumped solid state laser light source from which light is reflected by an array of sub-micron sized MEMS micromirrors. Each mirror in the array may be electrostatically tilted and displaced such that a beam of light striking it is reflected in a desired direction at a desired phase angle. In this manner, the device may operate as a photomask.

A photomask constituted by a liquid crystal array, a microfluidic array, a micromirror array, or any other suitable photomask as will be appreciated by those skilled in the art, can be used as the programmable optical shutter array in the system and method of the present invention. By programming the optical shutter array such that some regions thereof allow passage of the light therethrough whilst other regions block passage of the light, an image may be formed on a correctly positioned substrate having the light-sensitive additive.

The light source used may be a conventional lamp, an LED, or a laser, or a plurality of the same. The light source should be matched according to the sensitivity of the additive used in or with the substrate. In matching of the light source, the transmission capability of the programmable optical shutter array should be taken into account.

Where a plurality of light sources are used, they may operate to flood illuminate or scan relative to the array of programmable optical shutters. As an example of a flood illuminating embodiment of the invention, the light source may be a chiral film laser.

Additives of particular relevance to the system and method of the present application are susceptible to changing colour to one of at least two selectable colours upon irradiation, each selectable colour being different from the colour of the additive, if any, prior to irradiation, the colour being selectable according to a fluence level of the irradiation at a desired point on the substrate. In this manner, a multi-tonal colour image may be developed by adjusting the transmissivity of each optical shutter in the programmable array. The light source can also be modulated to determine an exposure time for the printing operation.

The system of the present invention finds particular application in the field of hand-held devices such as mobile telephones, PDAs, calculators, watches and laptop computers. Each of these hand-held devices typically comprise a liquid crystal display which can be utilised as the programmable optical shutter of the system of the present invention.

The traditional back light of such a liquid crystal display may be used as the light source of the present invention or a dedicated secondary light source may be employed in the hand-held device as the light source of the present invention. The type of light, i.e. the frequency and maximum brightness, and the type of light source, i.e. laser, lamp or LED etc., should be tuned to co-operate with the additive of the substrate.

By using an appropriately treated substrate, such that it has the requisite additive, an individual can portably print on demand whatever information is currently displayed on a display screen of his hand-held device without the need for any additional printer hardware.

Due to the ever decreasing cell size of liquid crystal cells, and emerging alternative photomask technologies such as those described above, the present invention enables ultra-high resolution colour printing from hand-held devices “on the fly”.

The system of the present invention may also be specifically adapted for use in custom-defined applications such as pricing and weight marking of articles in warehouses or supermarkets; or stamping and verification of articles such as passports, identity cards and the like.

In addition to hand-held devices, the present invention also finds application in household and industrial scale systems such printers. The system of the present invention can provide high resolution digital print capability at ultra high speed, far surpassing by some distance any other form of digital print process currently on the market.

### DESCRIPTION OF DRAWINGS

FIG. 1 is a schematic diagram illustrating a first embodiment of the system of the present invention;

FIG. 2 is a plan view of a shutter array for use in the system of the present invention;

FIG. 3 is a schematic diagram illustrating a second embodiment of the system of the present invention;

FIG. 4 is a schematic diagram illustrating a third embodiment of the system of the present invention;

FIG. 5 is a schematic diagram illustrating a fourth embodiment of the system of the present invention; and

FIG. 6 is a schematic diagram illustrating a fifth embodiment of the system of the present invention.

### DETAILED DESCRIPTION

Embodiments of the present invention will now be described with reference to the accompanying drawings.

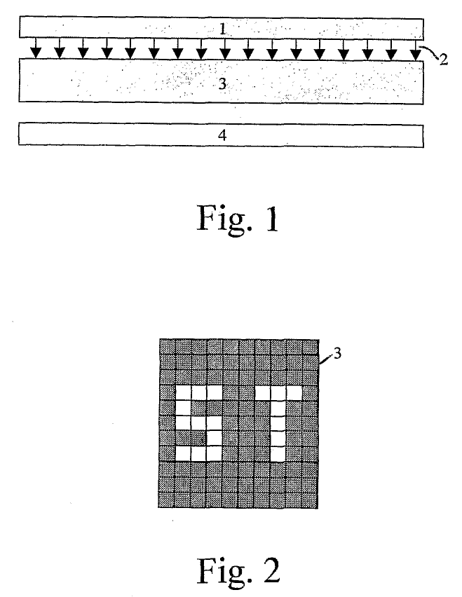

FIG. 1 shows a system arrangement of a first embodiment of the present invention. A light source 1 emits an energy beam 2 towards an array of programmable shutters 3. Each optical shutter in the array is selectively controlled to block or allow passage or some or all of the energy beam 2 entering the shutter array. Parts of the energy beam which are permitted to pass through the array of shutters 3 fall incident on a substrate 4 positioned adjacent the shutters. The substrate 4 includes an additive susceptible to changing colour upon irradiation with the energy beam.

The energy beam 2 of the first embodiment is a beam of laser light. The laser beam 2 is emitted by a laser light source 1. Various types of laser light sources may be used, for example, diode lasers, fibre-coupled diode lasers, laser diode arrays and diode-pumped solid-state lasers. In the first embodiment, the laser light source 1 is arranged to flood illuminate the shutter array. That is, the light beam 2 illuminates substantially all of the shutter array 3.

Since the energy beam 2 of the first embodiment is a light beam, the shutter array 4 is correspondingly an optical shutter array. The optical shutter array is programmable such that each shutter allows passage, or blocks, some light therethrough. FIG. 2 illustrates a pixelated liquid crystal optical shutter array as a purely exemplary shutter array for use in the present invention. Grey coloured pixels represent “closed” shutters through which passage of the light is not permitted, and, white coloured pixels represent “open” shutters through which transmission of the light is permitted.

The programmable optical shutter array 3 may either be once-programmable to generate a fixed image on the shutter array, or may be re-programmable such that the image generated thereon may be altered.

A pixelated liquid crystal optical shutter array 3 programmed as shown in FIG. 2 when incorporated in the system of FIG. 1 could produce an image of the letters “ST” on the substrate so long as suitable matching of the power output of the light source 1 and the additive of the substrate has been implemented.

The rudimentary embodiment described above is suitable for mono-tone imaging since the pixelated shutter array is operable between an “open” and a “closed” state. However, it will be appreciated by those skilled in the art that liquid crystal and other types of shutters such as those described previously can be adapted to permit varying degrees of energy through, precisely controlling the delivered fluence, and so operable to print in grey-scale or full multi-colour depending on the additive to be used with the substrate.

Control of the optical shutter array can be effected by known means such as a microcomputer or the like. The shutter control means may also be linked with means for modulating a power output of the light source 1 such that the light output by the optical shutter array can be accurately controlled.

Next will be described an example of a composition to be applied to the substrate 4 prior to printing with the system of the present invention. The composition comprises a solution of 10,12-pentacosadiynoic acid, Cyracure 6974 (photoacid generator), Elvacite 2028 (acrylic binder) and methyl ethyl ketone (MEK). This mixture is applied onto paper using a wire bar coater to provide an even coating of the mixture. This coating formulation is susceptible to colour change upon application of light energy in the form of laser light. A UV laser diode emitting in the 400-500 nanometer range is suitable for use in the system of the present invention with the above-mentioned formulation.

The above composition is one of a multitude suitable for use in the system of the present invention. Imaging at near-infrared and violet/ultraviolet wavelengths is particularly attractive since small and relatively inexpensive diode lasers are readily available at these wavelengths. Applicant's own PCT/GB 05/00121 and 0418676.3 provide further examples of compounds suitable for imaging at such wavelengths and therefore for use in the present invention.

The above described composition is transparent and clear and when coated on paper provides a similar reflectance spectrum to that of the bare paper. The reflectance of the coated paper remains substantially unchanged after irradiation with the laser diode to form an image on the substrate. This is particularly advantageous in that the problems of differential gloss apparent in many toner or ink based printing systems is overcome. The above described composition typically undergoes colour change from colourless to blue, to red, and finally to yellow by respective increases in the fluence level of an incident laser beam.

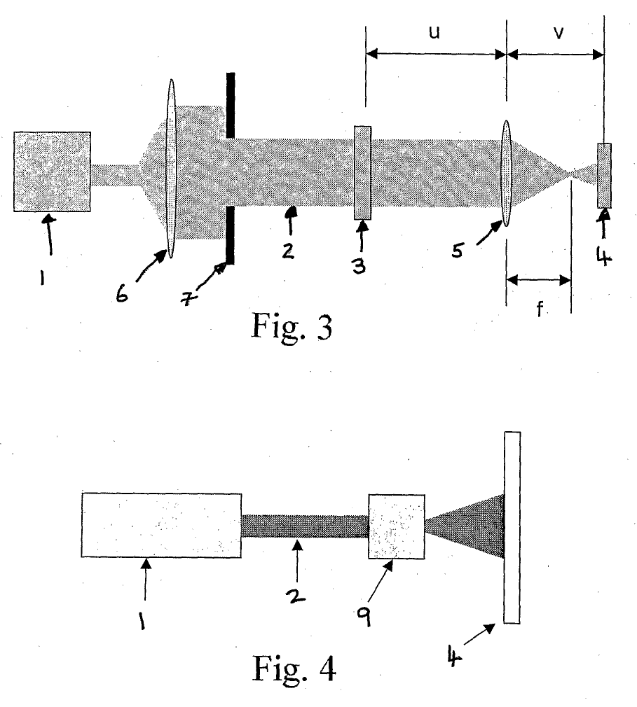

Further embodiments of the system of the present invention will now be described with reference to FIGS. 3 to 6 in which like numerals are used to denote like parts of the first embodiment.

FIG. 3 shows an example of a system in accordance with a second embodiment of the present invention. As in FIG. 1, the system is adapted to flood illuminate an optical shutter array, or photomask, 3 with a light beam 2 generated by a light source 1. The system is arranged in a, so-called, relay-imaging set-up. A lens 5 having a lens focal length f is used to relay an image produced on the photomask 3 onto the substrate 4. The lens 5 is disposed a distance u from the photomask 3, which distance must be greater than the lens focal length f (u>f). A demagnified image is formed on the substrate 4 at a distance v from the imaging lens 5 according to the well known formula (1/f)=((1/u+(1/v)). The demagnification ratio is given by (v/u).

For large demagnifications, several relay image systems can be cascaded in series, simply using the image plane of one system to act as the virtual mask for the next system. This negates the requirement for large path lengths (demagnification=v/u). Conversely, if a single demagnification is preferred and consequently large path lengths are required, the path can be concertinaed/folded using mirrors allowing a more compact design to be utilised.

In the system of FIG. 3, the light emitted by the light source 1 is expanded and clipped prior to relay imaging. The expanded light is focussed by a lens 6 and clipped by aperture 7. This allows a more uniform beam 2 profile to be generated and consequently more uniform illumination of the photomask 3. Ultimately, this allows each pixel of the photomask 3 to be irradiated with the same fluence level which is desirable for precise control of imaging parameters of the image ultimately to be printed on the substrate 4. The expansion and clipping of the beam prior to relay imaging is, however, not essential to the invention.

An autofocus system may be incorporated into the system of FIG. 3 such as those commercially available for use in cameras and the like. This would ensure that the relayed image would be sharply in focus at the substrate 4, avoiding the necessity to ensure the substrate is at the required focal point and thus further increasing the utility of the system.

An alternative mode of operation could utilise fourier transform imaging in a focused geometry. To accomplish this, the photomask 3 must be replaced by a fourier image mask of the required final image at the focus of the lens 5 instead of the image plane on the substrate 4 as per relay imaging. A simple focusing lens would then generate very detailed images in a small spot. Moreover, this also facilitates use of a relatively simple compact arrangement comprised of a single lens and fourier image mask.

It is als envisaged that the mask/beam manipulating optics could be replaced with a holographic optical element, or optical set-up capable of generating a holographic image in the substrate 4.

The beam manipulating optics and photomask 3 described above may be incorporated in a single optical unit 9 as shown in FIG. 4.

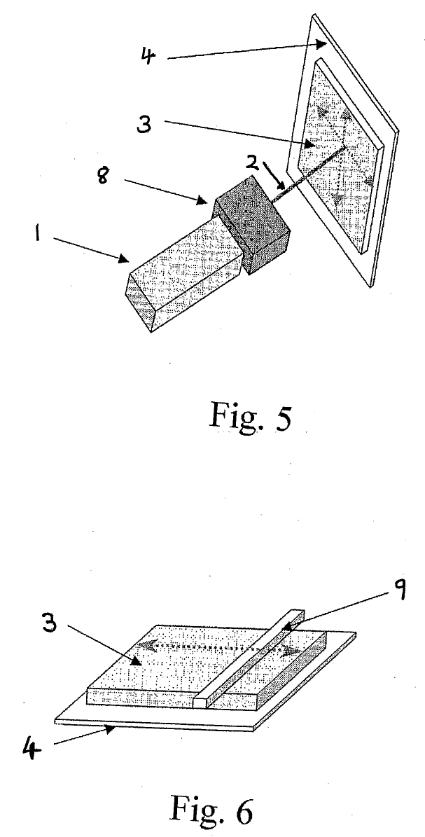

An alternative embodiment of the present invention will now be described with reference to FIG. 5 in which a laser beam 2 from a single laser source 1 is adapted to be raster-scanned across the photomask 3. This system of FIG. 5 utilises computer controlled mirrors within a scanning head 8 to direct and scan the laser beam 2 onto/across the programmable mask 3, resulting in imagewise exposure of the substrate 4 and ultimately inducing colour-change of the additive in predetermined areas. This embodiment may advantageously further comprise one or more features of the above or below described embodiments, as desired.

A yet further alternative embodiment will now be described with reference to FIG. 6 in which a laser diode array 9 as the light source is adapted to be moved scanwise across the programmable mask 3. The laser diode array 9 is formed as a bar which scans across the mask 3, illuminating each pixel of the mask (in a manner similar to the action of a photocopier/scanner). In the embodiment shown in FIG. 6 the bar is movable scanwise in one direction across the mask 3. However, it will be apparent to those skilled in the art that the substrate 4 and mask 3 may be together moved relative to the bar 9 to achieve the same object. It is also envisaged that the diode array/bar 9 may be moved XY scanwise relative to the mask 3 and substrate 4, but this may be less desirable as it may be more time consuming. The mask 3 is programmable to form an image on the substrate 4 in the same manner as previously described. This embodiment may advantageously further comprise one or more features of the above described embodiments, as desired.

The laser diode array/bar 9 may be replaced by one or more fibre-coupled diode lasers, or a single diode laser coupled to a series of optical fibres. Fibre-coupling may advantageously improve the quality of the light beam(s).

Various modifications of the purely exemplary embodiments described above will be apparent to those skilled in the art with reference to the foregoing without departing from the scope of the present invention.

1-34. (canceled)

35. An ink-less printing system comprising:
a laser light source for emitting a laser beam;
an array of programmable optical shutters, each adapted for selectively blocking or allowing passage of at least some of a laser beam therethrough; and,
a substrate including a diacetylene additive susceptible to changing colour when energized by the laser beam emitted by the laser light source,
wherein, in use, the laser beam passing through the array of optical shutters energizes at least one desired point on the substrate thus causing the diacetylylene additive to polymerize and thereby change colour at said point.

36. The system according to claim 35, wherein the laser light source and the array of programmable optical shutters are provided in a hand-held device.

37. The system according to claim 36, wherein the hand-held device is one from a group consisting of a mobile telephone, a PDA, a calculator, a watch, a laptop computer, or a printer.

38. The system according to claim 35, wherein a plurality of said laser light sources is provided in a linear or matrix way.

39. The system according to claim 38, wherein said plurality of laser light sources is operable to flood illuminate or scan relative to the array of programmable optical shutters.

40. The system according to claim 35, wherein the optical shutters are liquid crystal cells, or microfluidic devices, or micromirrors.

41. The system according to claim 35, wherein a power output of the laser light source is modulated.

42. The system according to claim 35, wherein a power transmission of the optical shutter is modulated.

43. The system according to claim 35, wherein the diacetylene additive is susceptible to changing colour to one of at least two selectable colours upon irradiation, each selectable colour different from the colour of the additive, if any, prior to irradiation, the colour being selectable, in use, according to a fluence level of the irradiation at the desired point on the substrate.

44. The system according to claim 35, wherein the additive further includes a photoacid or photobase.

45. The system according to claim 35, wherein the substrate material is selected from metals, alloys, glasses, ceramics, plastics, fabrics, wood, paper, card, resins, rubbers, foams, composites, stone and edibles.

46. A method of ink-less printing comprising the steps of:
providing a laser light source for emitting a laser beam;
providing an array of programmable optical shutters, each adapted for selectively blocking or allowing passage of at least some of a laser beam therethrough;
providing a substrate including a diacetylene additive susceptible to changing colour when energized by the laser beam emitted by the laser light source;
selectively allowing passage of at least some of the laser beam emitted by the laser light source through the array of optical shutters; and,
positioning the substrate in the path of the laser light beam that has passed through the array of optical shutters such that at least one desired point on the substrate is energized by said beam thus causing the diacetylene additive to polymerize and thereby change colour at said point.

47. The method according to claim 46, further comprising the step of controlling the laser lights source such that the laser beam emitted therefrom flood illuminates the array of optical shutters.

48. The method according to claim 46, further comprising the step of controlling the laser light source such that it scans relative to the array of optical shutters.

49. The method according to claim 46, further comprising the step of modulating a power output of the laser light source.

50. The method according to claim 46, further comprising the step of modulating a power transmission of at least one optical shutter in the array.

51. The method according to claim 46, wherein the step of providing the substrate includes the step of matching a concentration of diacetylene additive in the substrate to a range of fluence levels achievable with the laser light source and the array for optical shutters.

52. The method according to claim 46, wherein the step of selectively allowing passage of at least some of the laser beam emitted by the light source through the array of optical shutters includes the step of programming the programmable array of optical shutters.

53. The method according to claim 52, wherein the programming step creates a power transmission pattern across the optical shutter array.

54. The method according to claim 46, wherein a multi-tonal colour image is developed on the substrate by irradiation of the substrate at a plurality of fluence levels.
